(19) United States
(12) Patent Application Publication
(10) Pub. No.: US 2017/0188451 A1
(43) Pub. Date: Jun. 29, 2017

(54) FLEXIBLE CIRCUIT BOARD AND METHOD FOR MANUFACTURING SAME

(71) Applicants: FuKui Precision Component (Shenzhen) Co., Ltd., Shenzhen (CN); HongQiSheng Precision Electronics (QinHuangDao) Co.,Ltd., Qinhuangdao (CN); Zhen Ding Technology Co., Ltd., Tayuan (TW)

(72) Inventors: XIAN-QIN HU, Shenzhen (CN); FU-YUN SHEN, Shenzhen (CN); MING-JAAN HO, New Taipei (TW); YI-QIANG ZHUANG, Shenzhen (CN)

(21) Appl. No.: 15/078,214

(22) Filed: Mar. 23, 2016

(30) Foreign Application Priority Data
Dec. 28, 2015 (CN) 201511000338.8

(51) Int. Cl. H05K 1/02; H05K 3/40; H05K 3/46; H05K 1/09; H05K 1/14

(52) U.S. Cl. CPC H05K 1/0242; H05K 1/0298; H05K 1/09; H05K 1/144; H05K 3/4652; H05K 3/4611; H05K 3/4038; H05K 2201/05; H05K 2201/09236; H05K 2201/042

(57) ABSTRACT

A flexible circuit board includes a first circuit substrate, a second circuit substrate and a bonding layer. The first circuit substrate includes a first base layer, a first circuit layer, a second circuit layer and metal coating layer. The first circuit layer includes a signal line and at least two grounding lines. The metal coating layer encloses the signal line. The second circuit substrate includes a third circuit layer. The bonding layer is located between and bonding the first circuit substrate and the second circuit substrate. The second circuit layer, the third circuit layer are electrically coupled with the grounding lines by a plurality of electrically conductive holes. The first base layer, the bonding layer and the second circuit substrate cooperatively enclose a hermetic medium layer receiving the signal line. The hermitic medium layer is filled with air. A method for manufacturing the flexible circuit board is also provided.

### FIELD

The subject matter herein generally relates to printed circuit boards, and particularly to a flexible circuit board and a method for manufacturing the flexible circuit board.

### BACKGROUND

Signal loss of high frequency transmission passing through a signal line mainly comes from dielectric loss. The dielectric loss is proportional to dielectric loss factor and relative dielectric constant. Methods for manufacturing circuit boards generally apply liquid crystal polymer (LCP), teflon or pure bonding with low relative dielectric constant to be substrate layers enclosing the signal line. However, the dielectric loss of the set forth material is still high, which results in that the signal transmission line of a circuit board made by the set forth material has larger signal loss. In addition, due to the skin effect, the signal will have transmission loss during signal transmission.

### BRIEF DESCRIPTION OF THE DRAWINGS

Implementations of the present technology will now be described, by way of example only, with reference to the attached figures.

FIG. 1 is cross sectional view of a flexible circuit board of an embodiment of the present disclosure.

FIG. 2 is a diagrammatic view of a third circuit layer, a first circuit layer, a second circuit layer and a dielectric layer and a bonding layer in FIG. 1.

FIG. 3 is a flow chart of a method for manufacturing a flexible circuit board of an embodiment of the present disclosure.

FIG. 4 is a cross sectional view of a first copper clad laminate.

FIG. 5 is a cross sectional view of a first circuit layer formed by the first copper clad laminate in FIG. 4.

FIG. 6 is a cross sectional view of a dielectric layer laminated on the first circuit layer in FIG. 5.

FIG. 7 is a cross sectional view of a metal coating layer formed on the first circuit layer in FIG. 6.

FIG. 8 is a cross sectional view of a second copper clad laminate.

FIG. 9 is a cross sectional view of a bonding layer bonding the second copper clad laminate in FIG. 7 to the dielectric layer in FIG. 6.

FIG. 10 is a cross sectional view of a plurality of electrically conductive holes formed in the second copper clad laminate and the first copper clad laminate.

FIG. 11 is a cross sectional view of a second circuit layer and a third circuit layer formed from the second copper clad laminate and the first copper clad laminate.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a flexible circuit board. The flexible circuit board can include a first circuit substrate, a second circuit substrate and a bonding layer. The first circuit substrate includes a first base layer, a first circuit layer and a second circuit layer located at two opposite sides of the first base layer. The first circuit layer includes at least a signal line and at least two grounding lines spaced from and located at two opposites sides of and the signal line. The first circuit substrate further includes a metal coating layer enclosing the signal line on the first base layer. The second circuit substrate includes a third circuit layer. The bonding layer is located between and bonding the first circuit substrate and the second circuit substrate and located on the grounding lines of the first circuit layer. The second circuit layer, the third circuit layer are electrically coupled with the grounding lines by a plurality of electrically conductive holes. The first base layer, the bonding layer and the second circuit substrate cooperatively enclose a hermetic medium layer receiving the signal line therein. The hermitic medium layer is filled with air.

The present disclosure is described further in relation to a method for manufacturing a flexible circuit board. The method can include followings. A first copper clad laminate is provided and includes a first base layer and a first copper foil located at a side of the first base layer. A first circuit layer is formed from the first copper foil. The first circuit layer includes at least a signal line. A metal coating layer is enclosed the signal line on the first base layer. A second copper clad laminate and a bonding layer is provided. The bonding layer couples the second copper clad laminate to the first circuit layer. The first base layer, the bonding layer and the second copper clad laminate cooperatively enclose a hermetic medium layer receiving the signal line therein. The hermitic medium layer is filled with air.

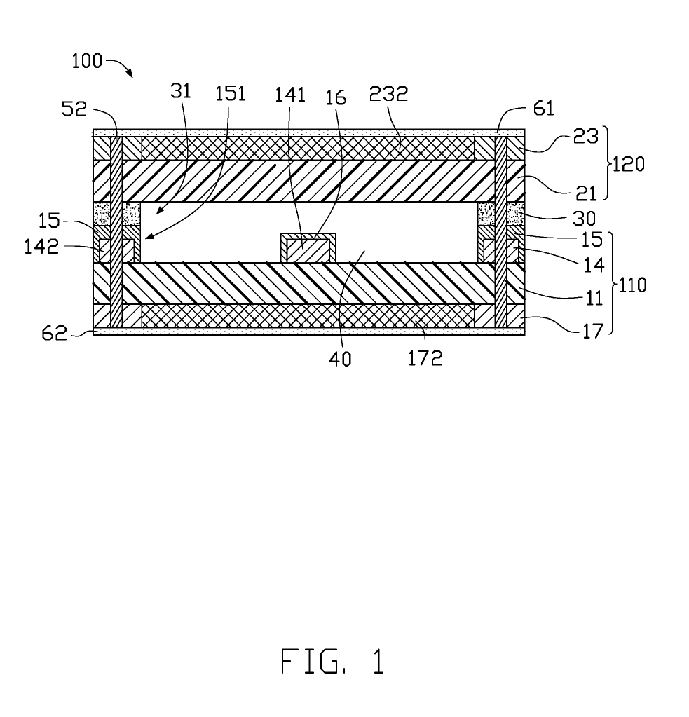

FIG. 1 illustrates a flexible circuit board 100. The flexible circuit board 100 can include a first circuit substrate 110, a second circuit substrate 120, a bonding layer 30 positioned between the first circuit substrate 110 and the second circuit substrate 120, a first protecting layer 61 covering an outer surface of the first circuit substrate 110 and a second protecting layer 62 covering an outer surface of the second circuit substrate 120.

The first circuit substrate 110 can include a first base layer 11, a first circuit layer 14 and a second circuit layer 17 located at two opposite sides of the first base layer 11. The first circuit substrate 110 can further include a dielectric layer 15 and a metal coating layer 16 both coupled to an outer face of the first circuit layer 14.

The first base layer 11 is flexible and located between the first circuit layer 14 and the second circuit layer 17. The first base layer 11 is a support layer configured to support the first circuit layer 14 and the second circuit layer 17. The first base layer 11 is an insulating layer. Material of the first base layer 11 can be one or more selected from polyimide (PI), polyethylene terephthalate (PET), polyethylene naphthalate (PEN), polyethylene (PE), teflon, liquid crystal polymer (LCP), polyvinyl chloride polymer (PVC) or other insulating material.

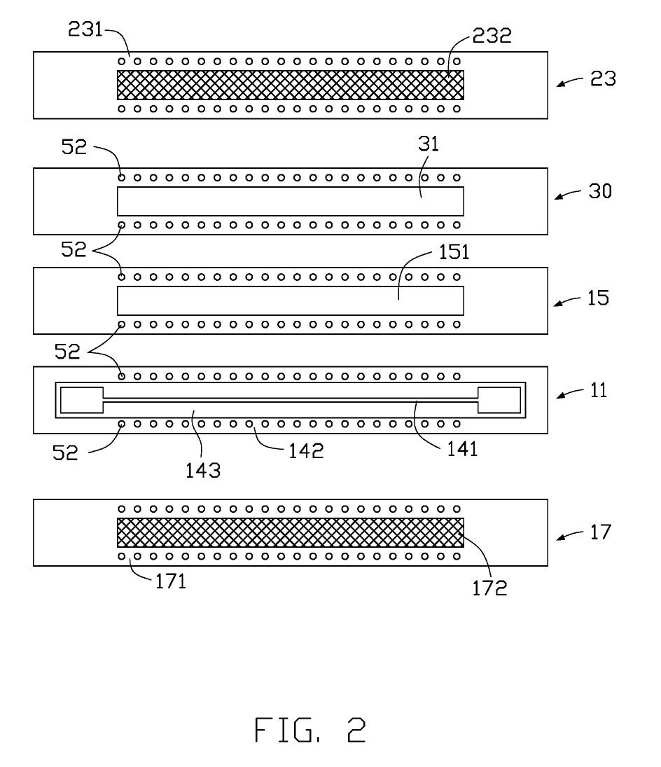

FIG. 2 illustrates that the first circuit layer 14 can include at least a signal line 141, and at least two grounding lines 142 located two opposite sides of the signal line 141.

In the illustrated embodiment, the first circuit layer 14 includes one signal line 141 and two grounding lines 142 located at two opposite sides of the signal line 141. The signal line 141 is located at a center portion of the first circuit layer 14. The first circuit layer 14 further defines two hollow areas 143 located at two opposite sides of the signal line 141 and between the two grounding lines 142.

In at least one embodiment, the signal line 141 can be electrically independent and insulated from two grounding lines 142. In the illustrated embodiment, the signal line 141 is electrically independent and insulating from two grounding lines 142 by the hollow areas 143. The signal line 141 is configured to transmit signals. The signal line 141 is copper which has better ductility, flexibility and electrically conductivity. Generally, electrical conductivity of copper is about 5.85×10⁷ Siemens/m (S/m). In at least one embodiment, the signal line 141 has a width less than that of each of the grounding lines 142.

The two grounding lines 142 can be parallel to each other. In at least one embodiment, the two grounding lines 142 can be symmetric to each other about the signal line 141. In at least one embodiment, the two grounding lines 142 and the signal line 141 are parallel to each other.

Each of the two grounding lines 142 has an extension direction that is the same as an extension direction of the signal line 141.

The dielectric layer 15 is laminated on the first circuit layer 14. The dielectric layer 15 defines a slot 151 corresponding to the signal line 141 of the first circuit layer 14. The slot 151 has a length along the extension direction of the signal line 141 substantially equal to that of the signal line 141. The slot 151 has a width no less than the width of the signal line 141. The dielectric layer 15 is spaced from the signal line 141 via the slot 151.

The dielectric layer 15 can be a composite dielectric layer. Material of the dielectric layer 15 can be polyimide, photosensitive cover-lay or other photosensitive, flexible material.

In at least one embodiment, the dielectric layer 15 encloses the grounding lines 142 on the first base layer 11. The grounding lines 142 are embedded in the dielectric layer 15. In at least one embodiment, the dielectric layer 15 directly contacts the first base layer 11.

The metal coating layer 16 encloses the signal line 141 on the first base layer 11. The metal coating layer 16 has a thickness less than a thickness of the signal line 141. The metal coating layer 16 has an electrical conductivity larger than that of the signal line 141. In at least one embodiment, the metal coating layer 16 is a silver layer with electrical conductivity about 6.3×10⁷ Siemens/m (S/m).

The metal coating layer 16 can be made by electroplating or chemical deposit which is facilitated to control the thickness of the metal coating layer 16, to thereby make the metal coating layer 16 in line with skin depth.

The skin depth is thickness of a conductor where the electric current flows through. In details, due to the high frequency signal during transmission having obvious skin effect, namely when high frequency electric current flows through a conductor, the electric current will not flow through a central portion of the conductor, but tend to flow through a skin or surface of the conductor. Therefore, the skin effect makes effective area of the conductor reduced, thus increasing resistance. As the frequency increases, the skin effect is also greater.

In other words, when the flexible circuit board 100 transmits high frequency signals, and the transmission frequency arrives at a certain range, the high frequency signals will be intensively transmitted by the metal coating layer 16 on the surfaces of the signal line 141, which reduces the loss of high frequency signal transmission.

The second circuit layer 17 can include a first grounding area 171 and a first hollow carved area 172. The first grounding area 171 is corresponding to the grounding lines 142 of the first circuit layer 14. The first hollow carved area 172 corresponds to the signal line 141 and the slot 151 of the dielectric layer 15.

The second circuit substrate 120 can include a second base layer 21 and a third circuit layer 23 located at a surface of the second base layer 21. The second base layer 21 faces the first circuit layer 14.

The second base layer 21 is flexible and is a support layer configured to support the third circuit layer 23. The second base layer 21 is an insulating layer. Material of the second base layer 21 can be one or more selected from polyimide, polyethylene terephthalate, polyethylene naphthalate, polyethylene, teflon, liquid crystal polymer, polyvinyl chloride polymer or other insulating material.

The third circuit layer 23 can include a second grounding area 231 and a second hollow carved area 232. The second grounding area 231 corresponds to the grounding lines 142 of the first circuit layer 14. The second hollow carved area 232 corresponds to the signal line 141 of the first circuit layer 14. In at least one embodiment, the second hollow carved area 232 corresponds to the signal line and the hollow areas 143 of the first circuit layer 14. The first hollow area 172 and the second hollow carved area 232 can be electrically coupled to the grounding lines 142 by a plurality of electrically conductive holes 52.

The bonding layer 30 is located between the dielectric layer 15 and the second base layer 21, and the bonding layer 30 bonds the dielectric layer 15 with the second base layer 21. The bonding layer 30 is located on an outer surface of the dielectric layer 15 remote from the first circuit layer 14. The bonding layer 30 defines an opening 31 corresponding to the slot 151 of the dielectric layer 15. The opening 31 has a size no less than a size of the slot 151. The bonding layer 30 is spaced from the signal line 141 via the slot 151 and the opening 31. The signal line 141 has an orthographic projection on the bonding layer 30 is located within the opening 31.

The bonding layer 30 and the dielectric layer 15 have a total thickness larger than a total thickness of the signal line 141 and the meal coating layer 16.

In at least one embodiment, the opening 31 has a length equal to the length of the slot 151. The opening 31 has a width equal to the width of the slot 151.

The hollow areas 143 of the first circuit layer 14, the slot 151 of the dielectric layer 15, and the opening 31 of the bonding layer 30 collective define a medium layer 40 enclosing the signal line 141. The air medium layer 40 is enclosed by first base layer 11, the dielectrically layer 15, the bonding layer 30, and the second base layer 21. The signal line 141 is spaced from the grounding lines 142, the dielectric layer 15, the bonding layer 30, and second base layer 21 via the hermitic medium layer 40.

In at least one embodiment, the hermitic medium layer 40 is filled with air, which has dielectric constant of the hermitic medium layer 40 is 1.0 farad/meter, which is less than a dielectric constant of teflon or liquid crystal polymer, so that, after signals are transmitted by the signal line 141, loss of the signals is reduced.

The plurality of electrically conductive holes 52 extend through the first circuit substrate 110, the dielectric layer 15, the bonding layer 30 and the second circuit substrate 120. The plurality of electrically conductive holes 52 electrically couple the second circuit layer 17 and the third circuit layer 23 with the grounding lines 142 of the first circuit layer 14.

In at least one embodiment, the plurality of electrically conductive holes 52 can be evenly and spaced arranged along the extension direction of the grounding lines 142. Alternatively, the electrically conductive holes 52 can be unevenly and spaced arranged along the extension direction of the grounding lines 142.

The first protecting layer 61 and the second protecting layer 62 are configured to protecting the second circuit layer 17 and the third circuit layer 23 from invasion of moisture or scratch of foreign matters.

In at least one embedment, the first protecting layer 61 and the second protecting layer 62 are cover-lay. In at least one alternative embodiment, the first protecting layer 61 and the second protecting layer 62 can be solder resist layers.

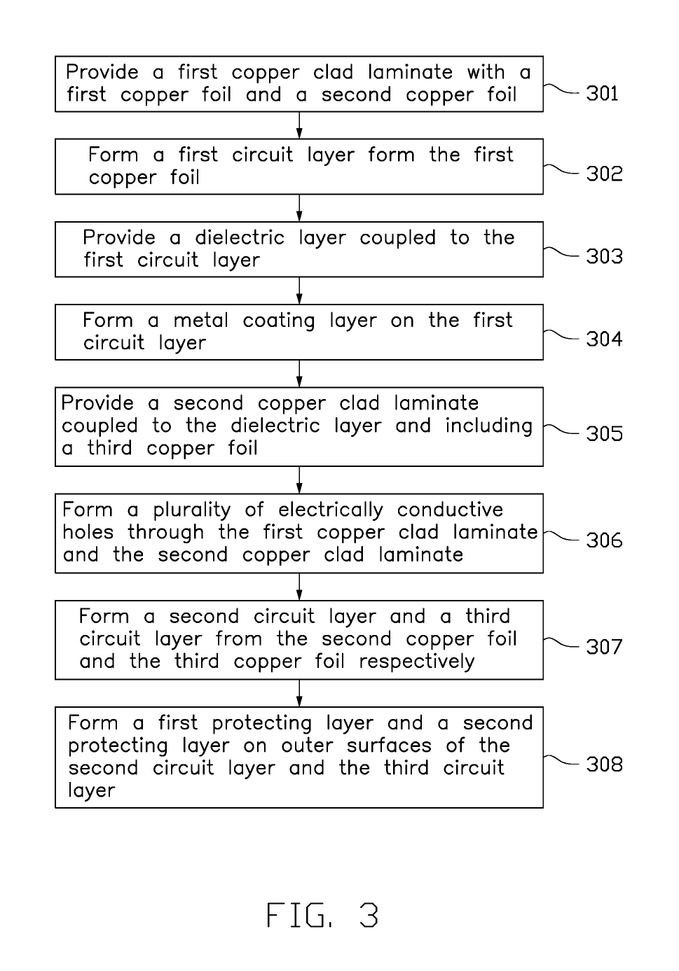

FIG. 3 illustrates a flowchart of an example method for manufacturing the flexible circuit board 100. The example method is provided by way of example, as there are a variety of ways to carry out the method. The example method described below can be carried out using the configurations illustrated in FIGS. 1, 2, and 4-11, for example, and various elements of these figures are referenced in explaining the example method. Each block shown in FIG. 3 represents one or more processes, methods or subroutines, carried out in the example method. Furthermore, the illustrated order of blocks is illustrative only and the order of the blocks can change according to the present disclosure. Additional blocks can be added or fewer blocks may be utilized, without departing from this disclosure. The example method can begin at block 301.

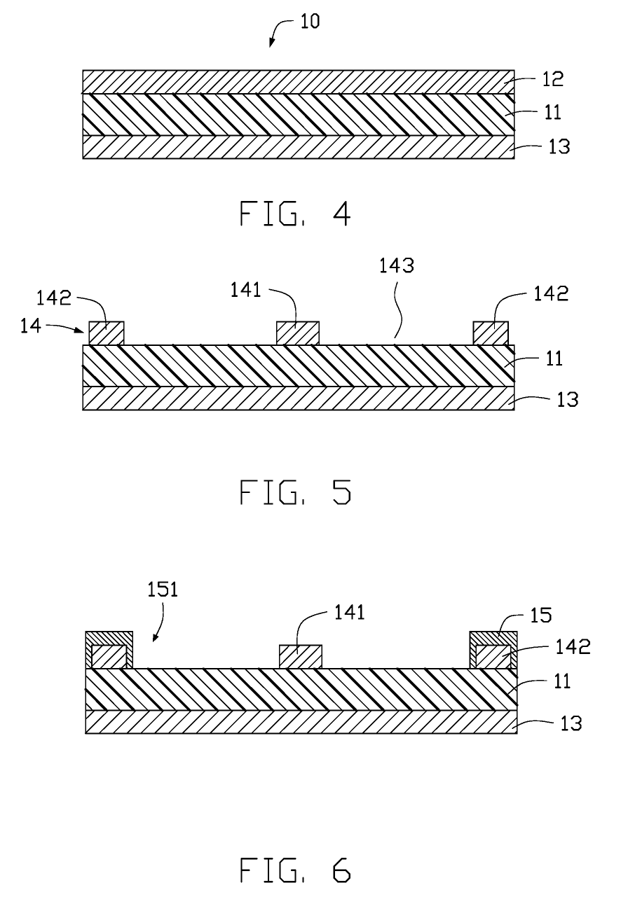

At block 301, also referring to FIG. 4, a first copper clad laminate 10 is provided.

The first copper clad laminate 10 can be a two-sided flexible copper foil laminate. The first copper clad laminate 10 includes a first base layer 11, a first copper foil 12 and a second copper foil 13 coupled to two opposite sides of the first base layer 11. In at least one alternative embodiment, the first copper clad laminate 10 can be a single-sided flexible copper foil laminate.

The first base layer 11 is flexible and located between the first copper foil 12 and the second copper foil 13. The first base layer 11 is a support layer configured to support the first copper foil 12 and the second copper foil 13. The first base layer 11 is an insulating layer. Material of the first base layer 11 can be one or more selected from polyimide, polyethylene terephthalate, polyethylene naphthalate, polyethylene, teflon, liquid crystal polymer, polyvinyl chloride polymer or other insulating material.

At block 302, also referring to FIG. 5, a first circuit layer 14 is formed form the first copper foil 12. The first circuit layer 14 is formed by process of image transfer and etching.

The first circuit layer 14 can include at least a signal line 141, and at least two parallel grounding lines 142 are located two opposite sides of the signal line 141.

In a least one embedment, the first circuit layer 14 includes one signal line 141 and two grounding lines 142 located at two opposite sides of the signal line 141. The signal line 141 is located at a center portion of the first circuit layer 14. The first circuit layer 14 further defines two hollow areas 143 located at two opposite sides of the signal line 141 and between the two grounding lines 142.

In at least one embodiment, the signal line 141 can be electrically independent and insulating from two grounding lines 142. In the illustrated embodiment, the signal line 141 is electrically independent and insulating from two grounding lines 142 by the hollow areas 143. The signal line 141 is configured to transmit signals. The signal line 141 is copper which has better ductility, flexibility and electrically conductivity. Generally, electrical conductivity of copper is about 5.85×10⁷ Siemens/m (S/m). In at least one embodiment, the signal line 141 has a width less than that of each of the grounding line 142.

In at least one embodiment, the two grounding lines 142 can be symmetric to each other about the signal line 141. In at least one embodiment, the two grounding lines 142 and the signal line 141 are parallel to each other.

The two grounding lines 142 each have an extension direction same to an extension direction of the signal line 141.

At block 303, also referring to FIG. 6, a dielectric layer 15 is provided and coupled to an outer face of the first circuit layer 14 remote from the first base layer 11.

The dielectric layer 15 encloses the grounding lines 142 of the first circuit layer 14 on the first base layer 11. The dielectric layer 15 defines a slot 151 corresponding to the signal line 141 of the first circuit layer 14. The slot 151 has a length along the extension direction of the signal line 141 substantially equal to that of the signal line 141. The slot 151 has a width no less than the width of the signal line 141. The dielectric layer 15 is spaced from the signal line 141 via the slot 151.

The slot 151 is formed by mechanical cutting, etching or other method.

The dielectric layer 15 can be a composite dielectric layer. Material of the dielectric layer 15 can be polyimide, photosensitive cover-lay or other photosensitive, flexible material. In the illustrated embodiment, the first slot 151 is formed by processes of exposure, developing and etching.

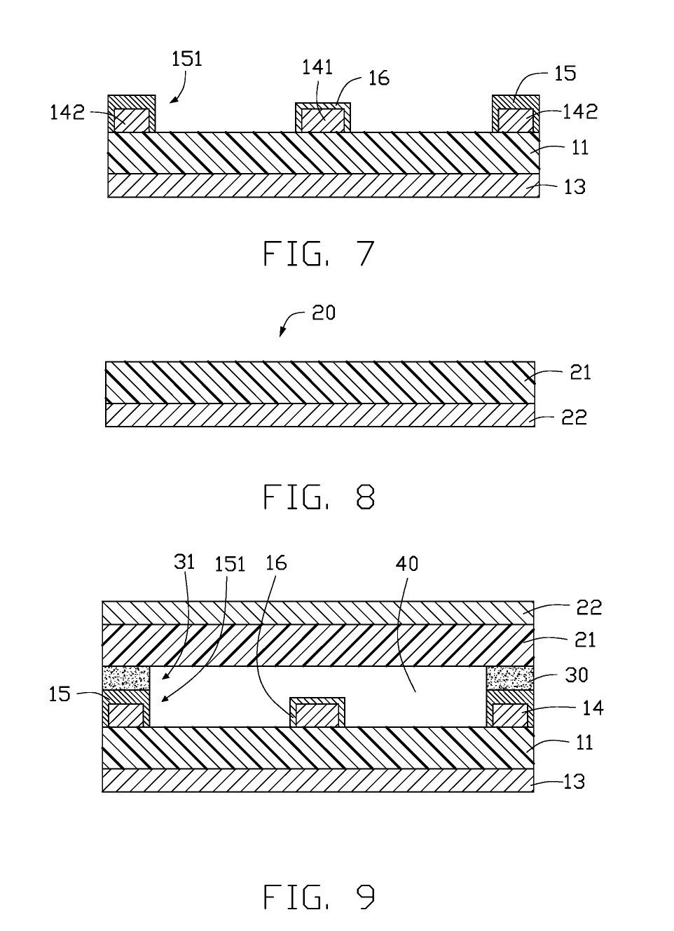

At block 304, also referring to FIG. 7, a metal coating layer 16 is formed on the signal line 141 of the first circuit layer 14.

The metal coating layer 16 encloses the signal line 141 on the first base layer 11. The metal coating layer 16 has a thickness less than a thickness of the signal line 141. The metal coating layer 16 has an electrical conductivity larger than that of the signal line 141. In at least one embodiment, material of the metal coating layer 16 can be silver with electrical conductivity about 6.3×10⁷ Siemens/m (S/m).

The metal coating layer 16 can be made by electroplating or chemical deposit which is facilitated to control the thickness of the metal coating layer 16.

At block 305, also referring to FIG. 8 and FIG. 9, a second copper clad laminate 20 is provided and coupled to an outer surface of the dielectric layer 15 by a bonding layer 30.

In at least one embodiment, the second copper clad laminate 20 can be a single-sided flexible copper foil laminate. The second copper clad laminate 20 can include a second base layer 21 and a third copper foil 22 located at a side of the second base layer 21.

The second base layer 21 is flexible, and is a support layer configured to support the third copper foil 22. The second base layer 21 is an insulating layer. Material of the second base layer 21 can be one or more selected from polyimide, polyethylene terephthalate , polyethylene naphthalate, polyethylene, teflon, liquid crystal polymer, polyvinyl chloride polymer or other insulating material.

The bonding layer 30 is located between the dielectric layer 15 and the second base layer 21, and bonding the dielectric layer 15 with the second base layer 21. The bonding layer 30 is located on the outer surface of the dielectric layer 15 remote from the first circuit layer 14. The bonding layer 30 defines an opening 31 corresponding to the slot 151 of the dielectric layer 15. The opening 31 has a size no less than a size of the slot 151. The bonding layer 30 is spaced from the signal line 141 via the slot 151 and the opening 31. The signal line 141 has an orthographic projection on the bonding layer 30 is located within the opening 31.

In at least one embodiment, the opening 31 has a length equal to the length of the slot 151. The opening 31 has a width equal to the width of the slot 151.

The slot 31 is formed by mechanical cutting, etching or other method.

The hollow areas 143 of the first circuit layer 14, the slot 151 of the dielectric layer 15 and the opening 31 of the bonding layer 30 collective define a medium layer 40 enclosing the signal line 141. The air medium layer 40 is enclosed by first base layer 11, the dielectric layer 15, the bonding layer 30 and the second base layer 21. The signal line 141 is spaced from the grounding lines 142, the dielectric line 15, the bonding layer 30 and second base layer 21 via the hermitic medium layer 40.

In at least one embodiment, the hermitic medium layer 40 is filled with air.

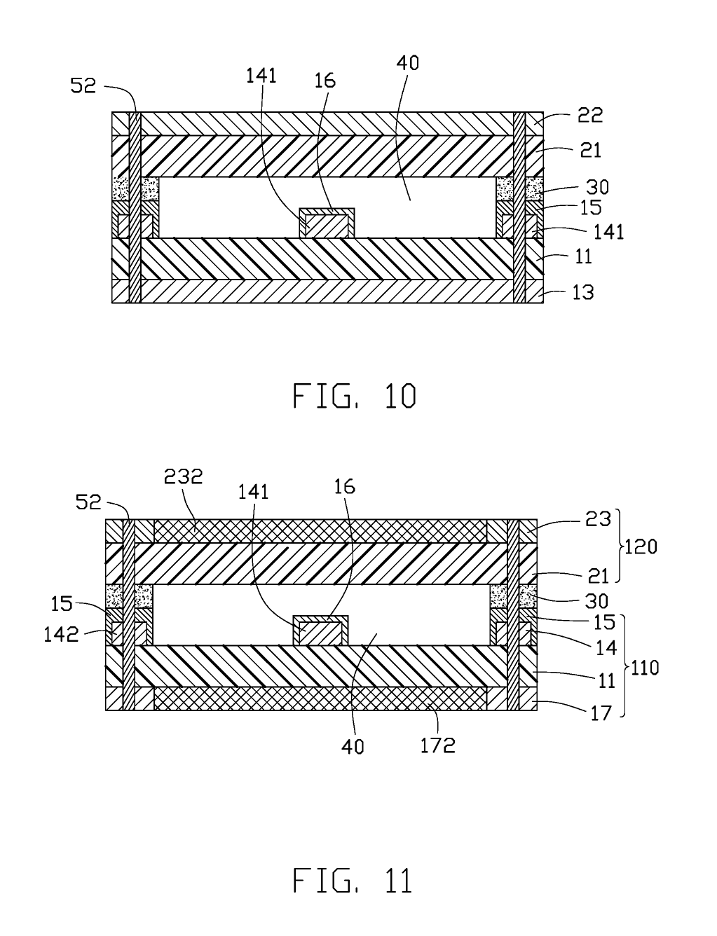

At block 306, also referring to FIG. 10, a plurality of electrically conductive holes 52 are formed.

The plurality of electrically conductive holes 52 extend through the flexible circuit board 100. The plurality of electrically conductive holes 52 electrically couple the second copper foil 13 of the first copper clad laminate 10, the third copper foil 22 of the second copper clad laminate 20 and the grounding lines 142 of the first circuit layer 14.

The plurality of electrically conductive holes 52 can be formed by the following method. A plurality of through holes or blind holes are defined by mechanically punching or laser etching. Electrically conductive material is filled in the through holes or blind holes.

In at least one embodiment, the plurality of electrically conductive holes 52 can be evenly and spaced arranged along the extension direction of the grounding lines 142. Alternatively, the electrically conductive holes 52 can be unevenly and spaced arranged along the extension direction of the grounding lines 142.

At block 307, also referring to FIG. 11 and FIG. 2, a second circuit layer 17 is formed from the second copper foil 13, to thereby form a first circuit substrate 110, and a third circuit layer 23 is formed from the third copper foil 22, to thereby form a second circuit substrate 120.

The second circuit layer 17 can include a first grounding area 171 and a first hollow carved area 172. The first grounding area 171 is corresponding to the grounding lines 142 of the first circuit layer 14. The first hollow carved area 172 is corresponding to the signal line 141 and the slot 151 of the dielectric layer 15.

The third circuit layer 23 can include a second grounding area 231 and a second hollow carved area 232. The second grounding area 231 is corresponding to the grounding lines 142 of the first circuit layer 14. The second hollow carved area 232 is corresponding to the signal line 141 of the first circuit layer 14. In at least one embodiment, the second hollow carved area 232 is corresponding to the signal line 141 and the hollow areas 143 of the first circuit layer 14.

The first hollow area 172 and the second hollow carved area 232 can be electrically coupled to the grounding lines 142 by the plurality of electrically conductive holes 52.

The first hollow area 172 and the second hollow carved area 232 both are corresponding to the hermitic medium layer 40.

The first circuit substrate 110 includes the first base layer 11, the first circuit layer 14, the second circuit layer 17, the dielectric layer 15 and the metal coating layer 16.

The second circuit substrate 120 includes the second base layer 21 and the third circuit layer 23. The electrically conductive holes 52 electrically couple the second circuit layer 17 and the third circuit layer 23 with the grounding lines 142.

At block 308, also referring to FIG. 1, a first protecting layer 61 and a second protecting layer 62 are formed on outer surfaces of the second circuit layer 17 and the third circuit layer 23, respectively.

The first protecting layer 61 and the second protecting layer 62 are configured to protecting the second circuit layer 17 and the third circuit layer 23 from invasion of moisture or scratch of foreign matters.

In at least one embedment, the first protecting layer 61 and the second protecting layer 62 are cover-lay. In at least one alternative embodiment, the first protecting layer 61 and the second protecting layer 62 can be solder resist layers.

In the illustrated embodiment, the flexible circuit board 100 is a three-layers circuit board. In at least one alternative embodiment, the flexible circuit board 100 can be a multi-layers circuit board.

In the illustrated embodiment, the dielectric layer 15 is configured to increase height of the hermitic medium layer 40 and protect the grounding lines 142 during forming the metal coating layer 16.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A flexible circuit board, comprising:
a first circuit substrate comprising a first base layer, a first circuit layer and a second circuit layer respectively, located at two opposite sides of the first base layer, the first circuit layer comprising:
at least a signal line and at least two grounding lines spaced from and located at two opposites sides of and the signal line, and
a metal coating layer enclosing the signal line on the first base layer;
a second circuit substrate comprising a third circuit layer; and
a bonding layer located between and bonding the first circuit substrate and the second circuit substrate, the bonding layer located on the grounding lines of the first circuit layer;
wherein the second circuit layer and the third circuit layer are electrically coupled with the grounding lines by a plurality of electrically conductive holes; the first base layer, the bonding layer and the second circuit substrate cooperatively enclose a hermetic medium layer receiving the signal line therein and filled with air.

2. The flexible circuit board of claim 1, wherein the bonding layer defines an opening corresponding to the signal line.

3. The flexible circuit board of claim 2, wherein the signal line has an orthographic projection on the bonding layer located within the opening.

4. The flexible circuit board of claim 1, wherein the metal coating layer has an electrical conductivity larger than that of the signal line, the metal coating layer having a thickness less than that of the signal line.

5. The flexible circuit board of claim 1, wherein the metal coating layer is a silver layer.

6. The flexible circuit board of claim 1, wherein the second circuit layer comprises a first grounding area and a first hollow carved area, the first grounding area being corresponding to and electrically coupled to the grounding lines, the first hollow carved area being corresponding to the hermitic medium layer.

7. The flexible circuit board of claim 6, wherein the third circuit layer comprises a second grounding area and a second hollow carved area, the second grounding area being corresponding to an electrically coupled to the grounding lines, the second hollow carved area being corresponding to the hermitic medium layer.

8. The flexible circuit board of claim 1, wherein the grounding lines are parallel to each other.

9. The flexible circuit board of claim 8, wherein the signal line is parallel to the grounding lines.

10. The flexible circuit board of claim 1, wherein the second circuit substrate comprises a second base layer coupled to the bonding layer, the third circuit layer being coupled to the second base layer.

11. The flexible circuit board of claim 1, wherein the first circuit substrate further comprises a dielectric layer coupled to the first circuit layer and enclosing the grounding lines on the first base layer, the dielectric layer defining a slot corresponding to the signal line, the dielectric layer being spaced from the signal line by the slot.

12. The flexible circuit board of claim 1, wherein the dielectric layer and the bonding layer have a total thickness larger than that of the metal coating layer.

13. A method for manufacturing a flexible circuit board, comprising:
providing a first copper clad laminate comprising a first base layer and a first copper foil located at a side of the first base layer;
forming a first circuit layer from the first copper foil, the first circuit layer comprising at least a signal line;
forming a metal coating layer enclosing the signal line on the first base layer; and
providing a second copper clad laminate and a bonding layer coupling the second copper clad laminate to the first circuit layer, the first base layer, the bonding layer and the second copper clad laminate cooperatively enclosing a hermetic medium layer receiving the signal line therein, the hermitic medium layer being filled with air.

14. The method of claim 13, wherein the first circuit layer further comprises at least two grounding lines located at two opposite sides of the signal line.

15. The method of claim 14, before forming a metal coating layer, further comprising:
providing a dielectric layer enclosing the grounding lines on the base layer.

16. The method of claim 15, wherein the dielectric layer defines a slot corresponding to the signal line, the dielectric layer being spaced from the signal line by the slot.

17. The method of claim 16, wherein the bonding layer defines an opening corresponding to the slot and the signal line, the bonding layer being spaced from the signal line by the slot and the opening.

18. The method of claim 13, wherein the first copper clad laminate further comprises a second copper foil located at an opposite of the first base layer, the second copper clad laminate comprising a second base layer and a third copper foil layer; the first base layer, the bonding layer and the second base layer cooperatively enclosing the hermitic medium layer receiving the signal line therein.

19. The method of claim 18, further comprising:
forming a second circuit layer from the second copper foil, and forming a third circuit layer from the third copper foil, the second circuit layer comprising a first grounding area and a first hollow carved area, the third circuit layer comprising a second grounding area and a second hollow carved area, the first grounding area and hate second grounding area both being corresponding and electrically coupled to the grounding lines, the first hollow carved area and the second hollow carved area being corresponding to the hermitic medium layer.

20. The method of claim 18, before forming the second circuit layer and the third circuit layer, further comprising:
forming a plurality of electrically conductive holes electrically coupling the second copper foil and the third copper foil with the grounding lines.
